(19) United States
(12) Patent Application Publication
(10) Pub. No.: US 2025/0224306 A1
(43) Pub. Date: Jul. 10, 2025

(54) PHOTONIC INTEGRATED CHIP, ARRAY AND TESTING METHOD THEREOF

(71) Applicant: SILITH TECHNOLOGY PTE. LTD., SINGAPORE (SG)

(72) Inventors: Xiaojun SHI, Shanghai (CN); Wenya ZHANG, Shanghai (CN); Ke ZHANG, Shanghai (CN)

(73) Assignee: SILITH TECHNOLOGY PTE. LTD., SINGAPORE (SG)

(21) Appl. No.: 18/921,007

(22) Filed: Oct. 21, 2024

(30) Foreign Application Priority Data
Jan. 9, 2024 (CN) 202410026184.2

(51) Int. Cl. G01M 11/00; G01M 11/02; G01R 31/28

(52) U.S. Cl. CPC G01M 11/33; G01M 11/0207; G01R 31/2837

(57) ABSTRACT

Present disclosure relates to field of semiconductor manufacturing, provides photonic integrated chip, array and testing method thereof. Chip includes functional assembly, light test assembly and electric test assembly manufactured through semiconductor process. Light test assembly and electric test assembly are connected respectively to different sides of functional assembly; functional assembly includes N functional units, and N is positive integer; each functional unit includes optical interface and first pad; first pad is configured to input or output electric signal in working environment; light test assembly includes main beam port and light splitting unit; input end of light splitting unit connects with main beam port; a plurality of output ends of light splitting unit connect with optical interfaces of N functional units; electric test assembly connects electrically with first pads, configured to test electrical performance of N functional units. Chip is configured to improve photoelectric test efficiency during wafer test.

### CROSS-REFERENCE TO RELATED APPLICATION

This application claims the priority benefit of China application serial no. 202410026184.2, filed on Jan. 9, 2024. The entirety of the above-mentioned patent application is hereby incorporated by reference herein and made a part of this specification.

### BACKGROUND

### Technical Field

The present application relates to the technical field of semiconductor manufacturing, and in particular to a photonic integrated chip, an array and a testing method thereof.

### Description of Related Art

Usually, before being cut, a photonic integrated chip (PIC) receives an optical or electrical performance testing on a wafer level, when the wafer is later being cut into a plurality of independent single chips, an unqualified chip having been marked shall be removed, instead of entering a next process, so as not to increase a manufacturing cost. However, as an area and a density of a chip are increasing, a test period for a wafer becomes longer and longer, which is not conducive to improving production efficiency.

In the prior art, for a silicon optical chip, an optical test method commonly used at a wafer level is coupling light into/out of a photonic chip through an arrayed waveguide optical fiber, the arrayed waveguide optical fiber is located on a side surface of the silicon optical chip, due to being limited by an amount of channels of the arrayed waveguide optical fiber and a distance between two optical fibers, only one chip can be optically coupled at a time, while the test period for a wafer is proportional to an amount of the chips, thus the test period for a wafer is long, with a high cost. Also, for a multi-channel arrayed waveguide optical fiber, it is not easy to be aligned accurately when being coupled, and a difference between different channels will introduce a test error. Therefore, it is urgently needed for a novel PIC, an array and a test method thereof, so as to improve the problems stated above.

### SUMMARY

The purpose of the present disclosure is providing a photonic integrated chip, an array and a test method thereof, wherein the chip is configured to improve a photoelectric test efficiency during wafer testing.

On a first aspect, the present disclosure provides a photonic integrated chip, comprising: a functional assembly, a light test assembly, and an electric test assembly manufactured by a semiconductor process; the light test assembly and the electric test assembly are connected respectively to different sides of the functional assembly; the functional assembly comprises N functional units, and N is a positive integer; each of the N functional units comprises an optical interface and a first pad; the first pad is configured to input or output an electrical signal in a working environment; the light test assembly comprises a main beam port and a light splitting unit; an input end of the light splitting unit is connected to the main beam port; each output end of the light splitting unit is connected to an optical interface of each of the N functional units; the electric test assembly is connected electrically to each of the first pads, configured to test an electric characteristic of the N functional units.

The present disclosure has a beneficial effect that: by arranging the main beam port and the light splitting unit, and arranging the output end of the light splitting unit being connected with the optical interfaces of the N functional units, it only requires to couple a single optical fiber to the main beam port, to achieve an optical test for the N functional units being implemented at a time, while an operation is convenient, a test efficiency is improved, there is no need to provide a multi-channel arrayed waveguide optical fiber, which is beneficial to reducing a test error.

Preferably, the electric test assembly comprises M second pads, M is a positive integer; at least a portion of the M second pads connect electrically with the first pads of the N functional units; the M second pads are configured to contact a test probe. A beneficial effect is: by arranging the second pads to contact the test probe, it is possible to avoid the first pad from being in direct contact with the test probe, and prevent a surface of the first pad from having a needle mark left, thus preventing the first pad from introducing a pollutant, and being beneficial to improving a yield.

Preferably, after testing the functional assembly, at least one of the light test assembly and the electric test assembly is separated from the functional assembly.

Preferably, after testing the functional assembly, N-P functional units are separated from each other, P is a non-negative integer less than N; a single functional unit after been separated is able to work independently.

Preferably, the beam splitting unit is configured to divide a main beam input from the main beam port into N beams of test light; the N beams of test light are input to the optical interfaces of the N functional units correspondingly through N optical waveguides.

Preferably, the N functional units are arranged on a surface of a wafer; the M second pads are arranged on the surface of the wafer, parallel to an arrangement direction of the N functional units.

Preferably, the M second pads are distributed at an equal interval on a side of the functional assembly away from the light test assembly.

On a second aspect, the present disclosure provides a photonic integrated chip array, comprising a plurality of the chips disclosed in any one of the first aspect arranged in an array.

On a third aspect, the present disclosure provides a photonic integrated chip testing method, configured to test the photonic integrated chip disclosed in any one of the first aspect, comprising a first step, a second step, a third step, wherein: the first step comprising coupling optically a test fiber to a main beam port and obtaining a plurality of optical test data of the N functional units; the second step comprising controlling a test probe to be in contact with the M second pads, wherein the M second pads are electrically connecting to the N functional units correspondingly to obtain a plurality of electrical test data of the N functional units; the third step comprising determining a test result of the N functional units according to the plurality of optical test data and the plurality of electrical test data.

Preferably, the second step further comprising: when a DC probe card is applied for testing, the DC probe card has M probes arranged, and the M probes contact with the M second pads one by one correspondingly and simultaneously.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic structural diagram on an photonic integrated chip having a plurality of functional units arranged along an X direction provided by the present disclosure;

FIG. 2 illustrates a schematic structural diagram on an photonic integrated chip having a plurality of functional units arranged along a Y-direction provided by the present disclosure;

FIG. 3 illustrates a schematic structural diagram on an photonic integrated chip having a plurality of sub-optical ports according to the present disclosure;

FIG. 4 illustrates a schematic diagram on an arrangement of a photonic integrated chip array along an X direction and a Y-direction according to the present disclosure;

FIG. 5 illustrates a schematic diagram on an arrangement of a photonic integrated chip array on a surface of a wafer along a Y-direction according to the present disclosure;

FIG. 6 illustrates a schematic flowchart on a testing method for a photonic integrated chip according to the present disclosure.

### DESCRIPTION OF THE EMBODIMENTS

In order to make the purpose, technical solution and advantages of the present application clearer and more explicit, further detailed descriptions of the present application are stated here, referencing to the attached drawings and some embodiments of the present application. Obviously, the described embodiments are part of, but not all of, the embodiments of the present application. Based on the embodiments of the present application, all other embodiments obtained by those of ordinary skills in the art without any creative work are included in the scope of protection of the present application. Unless otherwise defined, technical or scientific terms used herein should have the meanings usually understood by those of ordinary skills in the art to which the present application belongs. As used herein, the terms “comprise” and the like are intended to mean that an element or item appearing before the term encompasses elements or items appearing after the term and the equivalents thereof, instead of excluding other elements or items.

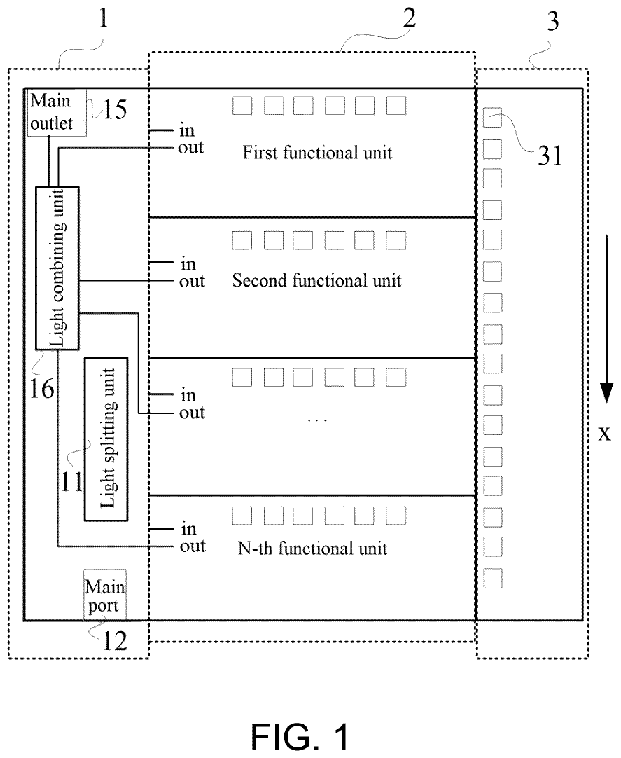

In view of the problems in the prior art, shown as FIG. 1, a first embodiment provides an photonic integrated chip, comprising: a functional assembly 2, a light test assembly 1, and an electric test assembly 3 manufactured by a semiconductor process; the light test assembly 1 and the electric test assembly 3 are connected respectively to different sides of the functional assembly 2; the functional assembly 2 comprises N functional units, and N is a positive integer; each of the functional units comprises an optical interface 21 and a first pad 22, totally N first pads 22; the first pad 22 is configured to input or output an electrical signal in a working environment; the light test assembly 1 comprises a main beam port 12 and a light splitting unit 11; an input end of the light splitting unit 11 is connected to the main beam port 12; each output end of the light splitting unit 11 is connected to an optical interface 21 of each of the N functional units; The electric test assembly 3 is connected electrically to the first pads 22, and is configured to test an electrical characteristic of the N functional units.

Specifically, the N functional units in the functional assembly 2 comprise at least one of a photon detector, a photon modulator, a photon filter, and a photon switch. The light test assembly 1 is configured to input an optical signal into the functional assembly 2, and the electric test assembly 3 is configured to input an electrical signal into the functional assembly 2, and output an electrical signal from the functional assembly 2.

It is noted that, the present embodiment, by arranging the main beam port 12 and the light splitting unit 11, and connecting the output end of the light splitting unit 11 to the optical interfaces 21 of the N functional units, it only requires to couple a single optical fiber to the main beam port 12, to achieve an optical test for the N functional units being implemented at a time, which is beneficial to improving a test efficiency, without requiring to provide a multi-channel arrayed waveguide optical fiber, which is beneficial to reducing a test error and saving a cost.

In a plurality of embodiments, the electric test assembly 3 comprises M second pads 31, M is a positive integer; at least a portion of the M second pads 31 are connected electrically to the first pads 22 of the functional unit; while the M second pads 31 are configured to be in contact with a test probe. In the present embodiment, by arranging the M second pads 31 to contact the test probe, it is possible to avoid the first pad 22 from being in direct contact with the test probe, and prevent a surface of the first pad 22 from having a needle mark left, thus preventing the first pad 22 from introducing a pollutant, and being beneficial to improving a yield.

Specifically, all the first pads 22 and the second pads 31 are made of metal. In an embodiment, the first pads 22 are electrically connected to the second pads 31 in an one-to-one manner. In order to meet a diversified electrical connection requirement during an electrical test, in a plurality of other embodiments, one first pad 22 is electrically connected to a plurality of second pads 31, so as to reduce a poor test caused by a poor contact between the second pads 31 and the probe. In further more embodiments, the functional unit has a plurality of first pads 22 having a same function arranged, and one second pad 31 is electrically connected to the plurality of first pads 22 having the same function, so as to save an amount of the probe used. In a plurality of other embodiments, the second pads 22 are attached to an edge of the functional assembly 2, which facilitates wire bonding during packaging.

In a plurality of embodiments, the N functional units are arranged on a surface of a wafer; the M second pads 31 are arranged on the surface of the wafer, parallel to an arrangement direction of the N functional units.

Shown as FIG. 1, in a plurality of embodiments, the light test assembly 1 further comprises a light combining unit 16 and a main beam outlet 15, the light combining unit 16 is connected to the N functional units through an optical waveguide. The N functional units output an optical signal to the light combining unit 16 through N paths of the optical waveguides, while the light combining unit 16 combines N paths of the optical signals into one path of optical signals before conducting to the main beam outlet 15. By coupling the main beam outlet 15, the present embodiment obtains a superimposed optical signal by combining the optical signals output from the N functional units.

When there is an abnormal optical signal output from the N functional units, by parsing a total power, frequency, or phase difference of the superimposed optical signal, the present embodiment is able to find that at least one of the N functional units is outputting an abnormal optical signal. An abnormal functional unit may be determined by testing the output optical signals from the N functional units one by one. The present embodiment is suitable for testing the photonic integrated chip in a mass production, thereby saving a test period for the optical signal output from the functional units in total. More specifically, the light combining unit 16 is configured as an N:1 combiner or an N:1 multiplexer.

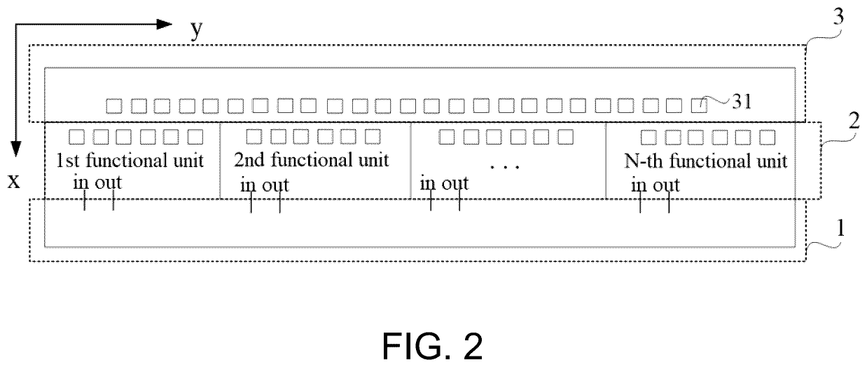

In a plurality of other specific embodiments, the N functional units are arranged in a row on the surface of the wafer along the X direction, and the M second pads 31 are arranged on the surface of the wafer in a row along the X direction. In a plurality of other specific embodiments, the M second pads 31 are distributed at an equal interval on a side of the functional assembly 2 away from the light test assembly 1. Shown as FIG. 2, in a plurality of specific embodiments, the N functional units are arranged in a row on the surface of the wafer along a Y-direction, while the light test assembly 1 is arranged on a side of the functional assembly 2 in an X-direction, and the electric test assembly 3 is arranged on a side of the functional assembly 2 reverse to the X-direction, the Y-direction is perpendicular to the X direction. It is noted that, an arrangement of the N functional units may be in any one manner, as long as meeting a requirement that the optical interface 21 is facing to the light test assembly 1 and the first pad 22 is facing to the electric test assembly 3, which is beneficial to reducing an optical loss and an electrical loss during a test.

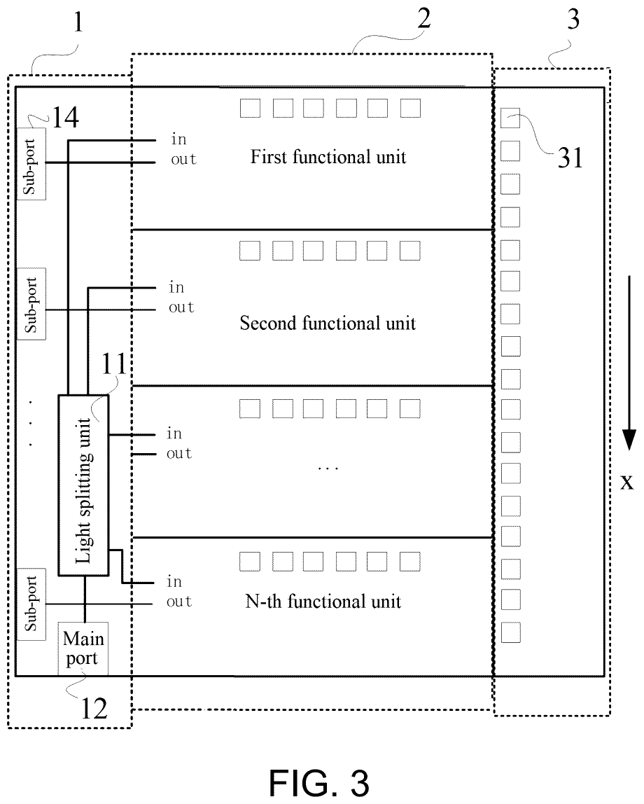

Shown as FIG. 3, in a plurality of more specific embodiments, the light test assembly 1 further comprises N optical sub-ports 14. The N optical sub-ports 14 are connecting correspondingly to each optical output end of the N functional units one by one, through the optical waveguides. Each of the N functional units outputs an optical signal to one of the optical sub-port 14 correspondingly through the optical waveguide. By coupling each optical sub-port 14 independently, the present embodiment is able to determine an optical signal parameter output from each functional unit, beneficial to determining an output light performance of each of the N functional unit.

In a plurality of embodiments, after testing the functional assembly 2, at least one of the light test assembly 1 and the electric test assembly 3 is separated from the functional assembly 2. Specifically, after testing the functional assembly 2, the light test assembly 1 and the functional assembly 2 are separated. In a plurality of other specific embodiments, after testing the functional assembly 2, the electric test assembly 3 and the functional assembly 2 are separated. In a plurality of more specific embodiments, after testing the functional assembly 2, both the light test assembly 1 and the electric test assembly 3 are separated from the functional assembly 2.

It is noted that, the light test assembly 1 or the electric test assembly 3 that is not separated from the functional assembly 2, may be used for a self-inspection of the functional assembly 2 in a working environment. When it is determined that the functional units in the functional assembly 2 are all able to receive the optical signal normally, the light test assembly 1 separated from the functional assembly 2 may be considered as a byproduct produced with the functional assembly 2.

In a plurality of embodiments, after testing the functional assembly 2, N-P functional units are separated from each other, wherein P is a non-negative integer less than N; a single functional unit after been separated is able to work independently.

Specifically, after testing the functional assembly 2, the N functional units are separated from each other. In a plurality of other specific embodiments, every two adjacent functional units have a circuit connection and/or an optical waveguide 13 connected, so as to form a functional group working cooperatively, while N/2 functional groups separated from each other may work independently. It is noted that the functional group may be composed of any number of the N functional units.

It is noted that the functional assembly 2, the light test assembly 1 and the electric test assembly 3 are integrated on a same wafer by a semiconductor process. By cutting the wafer, it is achieved that the light test assembly 1 and the electric test assembly 3 are separated from the functional assembly 2, and the N functional units are separated from each other. The semiconductor process comprises at least one of photolithography, etching, doping, thin film deposition, and metallization. In a plurality of specific embodiments, the main beam port 12 is arranged at an edge of the light test assembly 1. In a plurality of other specific embodiments, a coupling direction of the main beam port 12 is perpendicular to the surface of the wafer, and the main beam port 12 may be arranged at any position of the light test assembly 1.

In a plurality of embodiments, the light splitting unit 11 is configured to split a beam of total light input from the main beam port 12 into N beams of test light, and the N beams of test light are input correspondingly to the optical interfaces 21 of the N functional units through the optical waveguides 13 of N.

Specifically, the light splitting unit 11 is arranged as a 1:N-path optical splitter or a 1:N-path demultiplexer. In an embodiment, the 1:N-path optical splitter is configured as a planar waveguide optical splitter, an optical fiber optical splitter, an integrated optical splitter, or a wavelength selective optical splitter.

It is noted that, since the optical interface 21 and the second pad 31 are arranged at two opposite ends of each of the N functional units, the present embodiment is applicable to a plurality of functional units having the optical interface 21 close to the first pad 22, facilitating to miniaturizing the functional units and testing.

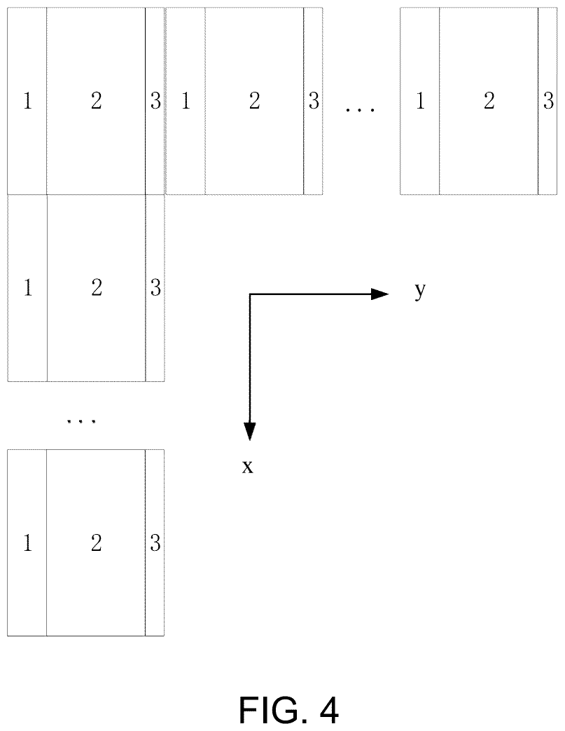

Shown as FIG. 4, a second embodiment provides a photonic integrated chip array, comprising a plurality of the chips disclosed in any one of the embodiments above, and the plurality of chips are arranged in an array. Specifically, the plurality of chips are arranged on the surface of the wafer in the Y-direction. In another specific embodiment, the plurality of chips are arranged on the surface of the wafer in the X direction.

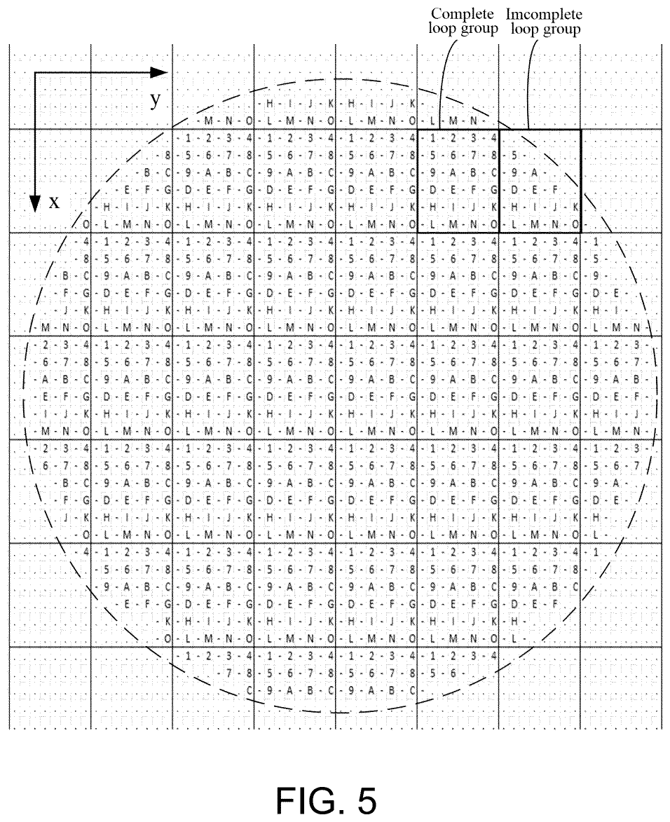

Shown as FIG. 5, in an embodiment, 24 functional units (1, 2, 3, . . . , N, O) arranged in a matrix shape are defined as a complete loop group, and between two adjacent functional units in each loop group, there are a light test assembly and an electric test assembly arranged correspondingly. The surface of the wafer is defined with a plurality of complete loop groups and a plurality of incomplete loop groups. The incomplete loop groups are located at an edge of the wafer, due to a circumference of the wafer divides a complete loop group into an incomplete circulation group. However, each functional unit in the incomplete loop group is still complete.

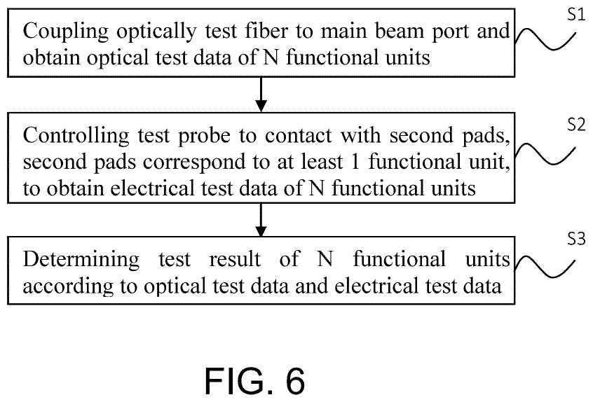

Shown as FIG. 6, a third embodiment provides a method for testing the photonic integrated chip, configured to test the chip disclosed in any one of the embodiments above, comprising: S1, coupling optically a test fiber to a main beam port and obtaining a plurality of optical test data of the N functional units; S2, controlling a test probe to be in contact with the M second pads, wherein the M second pads are electrically connecting to the N functional units correspondingly to obtain a plurality of electrical test data of the N functional units; S3, determining a test result of the N functional units according to the plurality of optical test data and the plurality of electrical test data.

Specifically, in S1, the test optical fiber is arranged as a single-beam optical fiber, and the light splitting unit is arranged as an optical splitter. A first end of the single-beam optical fiber is coupled to the main beam port, and a second end of the single-beam optical fiber has to optical transceiver coupled. The optical transceiver is arranged to transmitting a main beam signal through the single-beam optical fiber, the optical splitter divides the main beam signal into N-paths of optical signal, and the N-paths of optical signal are input to the optical interfaces of the N functional units correspondingly.

In a plurality of other specific embodiments, a total amount of the first pads is as same as a total amount of the second pads. The first pads and the second pads are contacted electrically and one by one correspondingly. In an embodiment, a total number of the second pads is M=N*i, wherein i is an amount of the first pads arranged in each of the N functional units.

In a plurality of embodiments, S2 comprises: when adopting a DC probe card for testing, the DC probe card has M probes arranged, and the M probes are contacting with the M second pads one by one correspondingly and simultaneously.

It is noted that, after S3 has been executed, the method further comprises: when a test result of the N functional units is poor, marking a corresponding unqualified functional unit as an unqualified product, and the unqualified product will no longer enter a next process, so as not to increase a manufacturing cost. The present embodiment, by one time contacting for the electric test and one time optical coupling for the light test, is able to achieve a test to the N functional units on a wafer level, and improve a test efficiency to N times of that in the prior art. Also, the light test and the electric test stated above are able to be executed synchronously to implement a photoelectric joint test, so as to further improve the test efficiency.

While the embodiments of the present application have been described in detail above, it will be apparent to those skilled in the art that various modifications and variations can be made to the embodiments. It should be understood, however, that such modifications and variations are within the scope and spirit of the present application as set forth in the claims. Moreover, the present application described herein is capable of other embodiments and of being practiced or of being carried out in various ways.

What is claimed is:

1. A photonic integrated chip, comprising: a functional assembly, a light test assembly, and an electric test assembly manufactured by a semiconductor process,
wherein the light test assembly and the electric test assembly are respectively connected to different sides of the functional assembly,
wherein the functional assembly comprises N functional units, and N is a positive integer, each of the N functional units comprises an optical interface and a first pad, the first pad is configured to input or output an electrical signal in a working environment,
wherein the light test assembly comprises a main beam port and a light splitting unit, an input end of the light splitting unit is connected to the main beam port, each output end of the light splitting unit is connected to an optical interface of each of the N functional units,
wherein the electric test assembly is electrically connected to each of the first pads, configured to test an electric characteristic of the N functional units.

2. The photonic integrated chip according to claim 1, wherein the electric test assembly comprises M second pads, M is a positive integer, at least a portion of the M second pads connect electrically with the first pads of the N functional units, the M second pads are configured to contact a test probe.

3. The photonic integrated chip according to claim 2, wherein after testing the functional assembly, at least one of the light test assembly and the electric test assembly is separated from the functional assembly.

4. The photonic integrated chip according to claim 2, wherein after testing the functional assembly, (N-P) ones of the functional units are separated from each other, P is a non-negative integer less than N; a single one of the functional units after been separated is able to work independently.

5. The photonic integrated chip according to claim 2, wherein the N functional units are arranged on a surface of a wafer;
the M second pads are arranged on the surface of the wafer, parallel to an arrangement direction of the N functional units.

6. The photonic integrated chip according to claim 5, wherein the M second pads are distributed at an equal interval on a side of the functional assembly away from the light test assembly.

7. The photonic integrated chip according to claim 1, wherein after testing the functional assembly, at least one of the light test assembly and the electric test assembly is separated from the functional assembly.

8. The photonic integrated chip according to claim 1, wherein the beam splitting unit is configured to divide a main beam input from the main beam port into N beams of test light; the N beams of test light are input to the optical interfaces of the N functional units correspondingly through N optical waveguides.

9. A photonic integrated chip array, comprising a plurality of the photonic integrated chips of claim 1 arranged in an array.

10. The photonic integrated chip array according to claim 9, wherein the electric test assembly comprises M second pads, M is a positive integer, at least a portion of the M second pads connect electrically with the first pads of the N functional units, the M second pads are configured to contact a test probe.

11. The photonic integrated chip array according to claim 10, wherein after testing the functional assembly, at least one of the light test assembly and the electric test assembly is separated from the functional assembly.

12. The photonic integrated chip array according to claim 10, wherein after testing the functional assembly, (N-P) ones of the functional units are separated from each other, P is a non-negative integer less than N; a single one of the functional units after been separated is able to work independently.

13. The photonic integrated chip array according to claim 10, wherein the N functional units are arranged on a surface of a wafer;
the M second pads are arranged on the surface of the wafer, parallel to an arrangement direction of the N functional units.

14. The photonic integrated chip array according to claim 13, wherein the M second pads are distributed at an equal interval on a side of the functional assembly away from the light test assembly.

15. The photonic integrated chip array according to claim 9, wherein after testing the functional assembly, at least one of the light test assembly and the electric test assembly is separated from the functional assembly.

16. The photonic integrated chip array according to claim 9, wherein the beam splitting unit is configured to divide a main beam input from the main beam port into N beams of test light; the N beams of test light are input to the optical interfaces of the N functional units correspondingly through N optical waveguides.

17. A photonic integrated chip testing method, configured to test the photonic integrated chip of claim 2, wherein the photonic integrated chip testing method comprising a first step, a second step and a third step, wherein
the first step comprising coupling optically a test fiber to a main beam port and obtaining a plurality of optical test data of the N functional units;
the second step comprising controlling a test probe to be in contact with the M second pads, wherein the M second pads are electrically connecting to the N functional units correspondingly to obtain a plurality of electrical test data of the N functional units;
the third step comprising determining a test result of the N functional units according to the plurality of optical test data and the plurality of electrical test data.

18. The photonic integrated chip testing method according to claim 17, wherein the second step further comprising: when a DC probe card is applied for testing, the DC probe card has M probes arranged, and the M probes contact with the M second pads one by one correspondingly and simultaneously.
